(19) United States
(12) Patent Application Publication
(10) Pub. No.: US 2007/0182027 A1
(43) Pub. Date: Aug. 9, 2007

(54) Integrated circuit and operating method therefor

(75) Inventor: Lutz Dathe, Dresden (DE)

Correspondence Address: MCGRATH, GEISSLER, OLDS & RICHARDSON, PLLC, P.O. BOX 1364, FAIRFAX, VA, 22038-1364, US

(73) Assignee: ATMEL Germany GmbH

(21) Appl. No.: 11/702,102

(22) Filed: Feb. 5, 2007

(30) Foreign Application Priority Data
Feb. 3, 2006 (DE) DE102006005779.1

(51) Int. Cl. H03K 3/00

(52) U.S. Cl. 257/786; 327/199; 257/686

(57) ABSTRACT

An integrated circuit is provided that includes at least one first circuit component and at least one second circuit component, the first circuit component being connected via a level converter to the second circuit component. The level converter can be optionally activated or deactivated by the first circuit component in order to enable or prevent a data exchange between the first circuit component and the second circuit component.

This nonprovisional application claims priority under 35 U.S.C. § 119(a) to German Patent Application No. DE 102006005779, which was filed in Germany on Feb. 3, 2006, and which is herein incorporated by reference.

### BACKGROUND OF THE INVENTION

1. Field of the Invention

The present invention relates to an integrated circuit with at least one first circuit component and with at least one second circuit component, the first circuit component being connected via a level converter to the second circuit component. The invention relates furthermore to an operating method for an integrated circuit of this type.

2. Description of the Background Art

Integrated circuits are known in the art, and a level converter is typically used to convert the level of signals such as, e.g., the voltage level, which are exchanged between circuit components, connected to one another via the level converter, in appropriate data lines or control lines.

### SUMMARY OF THE INVENTION

It is an object of the present invention to provide an integrated circuit having increased flexibility and reliability.

This object is achieved by a generic integrated circuit according to an embodiment of the invention in that the level converter can be optionally activated or deactivated by the first circuit component in order to enable or prevent a data exchange between the first circuit component and the second circuit component.

This makes it possible, for instance, to deactivate the level converter selectively whenever no data exchange occurs between the first circuit component and the second circuit component. It is also possible to prevent, in this way, that undefined signal states, which, e.g., can come temporarily from the second circuit component, are passed on to the first circuit component, as a result of which the reliability of the integrated circuit is increased. Such undefined signal states can occur, for instance, when the second circuit component is deactivated, particularly in order to shift to a rest state or the like. It is also conceivable to deactivate the level converter when it is suspected that the second circuit component has a disruption of operation or another defect.

An activation of the level converter accordingly can occur selectively whenever a data exchange between the first circuit component and the second circuit component is to occur, or if it is established that no undefined signal states come from the second circuit component.

The activation or deactivation of the level converter in an embodiment of the present invention can occur with the use of a relatively simple logic circuit, which provides a blocking of one or more signals passed through the level converter, for example, by one or more AND gates. This logic circuit can be integrated advantageously, also at least partially, into the level converter.

In addition to the mere blocking of the signals, the level converter within the scope of deactivation can also be separated from the supply voltage assigned to it, which is particularly expedient in configurations in which the level converter has a non negligible quiescent current uptake. In this case, the blocking of the signals can be carried out by a logic circuit, which is assigned to the level converter and, for example, is disposed between the first circuit component and the level converter. As a result, the occurrence of irregular or undefined signal states at the respective signal inputs of the first circuit component is also advantageously avoided, which otherwise could occur due to the separation of the level converter itself from its supply voltage.

Analogous to the logic circuit disposed between the first circuit component and the level converter, another logic circuit may also be provided, which is disposed between the second circuit component and the level converter and is used to block the signals relative to the second circuit component.

In an embodiment of the present invention, the level converter is configured so that in its deactivated state, it emits a predefined signal to the first circuit component and/or to the second circuit component. In the case of a single signal line, this can be a predefined logic level, for instance. If several signal lines are passed through the level converter, accordingly a predefined logic level can be output for each of these several signal lines to the first circuit component and/or to the second circuit component, while the level converter is deactivated.

In another embodiment of the present invention, the first circuit component has a first operating voltage range, and the second circuit component has a second operating voltage range, which is different from the first operating voltage range. It is possible, as a result, to provide different types of circuit components in the integrated circuit of the invention, so that there is an increased flexibility of the integrated circuit.

The first circuit component can be designed, for instance, using a first semiconductor technology with feature sizes of about 0.36 μm, whereas the second or additional circuit components can be designed using a different semiconductor technology, for instance, with feature sizes of about 0.18 μm. The integrated circuit of the invention can be optimized, with respect to its functionality and the needed chip area, by this combination of different semiconductor technologies.

The first circuit component according to another embodiment can have a greater operating voltage range than the second circuit component. This configuration is present, e.g., in the aforementioned example. The first circuit component with feature sizes of about 0.36 μm has an operating voltage range of about 1.8 V to about 3.75 V, whereas the second circuit component with feature sizes of about 0.18 μm can have an operating voltage range of about (1.8±10%) V.

This division of operating voltage ranges advantageously makes it possible to connect the first circuit component directly to an external voltage source such as, e.g., to a battery, whereas the use of components with a higher integration level is possible simultaneously because of the second circuit component with its smaller feature size and its accordingly smaller operating voltage range.

Another embodiment has a terminal for connecting the integrated circuit to an external voltage source. This terminal can be connected directly to the first circuit component.

In another embodiment of the present invention, at least one voltage regulator, which is activated or deactivated by the first circuit component, is provided for supplying the second circuit component and/or additional circuit components, so that the voltage or energy supply of the specific circuit components can be selectively turned off, as a result of which the power consumption of the integrated circuit is accordingly reduced.

It is possible to prevent a data exchange between the first circuit component and the additional circuit components by the level converter, controllable according to the invention, particularly during the turning on or off of the voltage or energy supply, in order to prevent the occurrence of undefined signal states at the corresponding signal inputs of the first circuit component.

In one respect, the power consumption of the voltage regulator is advantageously minimized per se, i.e., the power needed for its operation, by means of the deactivation of a voltage regulator supplying, e.g., the second circuit component. In addition, a non negligible power consumption by the second circuit component itself, due to leakage currents particularly in the case of small feature sizes, is avoided.

Whereas the second or additional circuit components of the integrated circuit of the invention are deactivated during nonuse in the previously described manner, the first circuit component can remain permanently connected to its assigned voltage supply such as, e.g., an external battery or the like. Due to the relatively large feature sizes of, e.g., about 0.36 μm, in comparison with the second circuit component, the leakage currents within the first circuit component are much smaller, so that the power consumption caused as a result is typically negligible.

Nevertheless, as many elements or components as possible of the integrated circuit of the invention are disposed in the circuit components with the smallest features size possible, in order to be able to utilize the attendant advantages of the higher integration density and the ability to deactivate the respective voltage regulator.

In order to assure reliable operation of the integrated circuit, in another embodiment of the present invention, at least one memory element, for example, a flip-flop, can be provided in the first circuit component and/or a state machine provided in the first circuit component. The state machine can be made, for instance, of a plurality of flip-flops. The memory element(s) or the state machine can be used for storing operating states of the different circuit components of the integrated circuit and assure permanent data retention, because the first circuit component is connected preferably directly to an external voltage supply or is not temporarily deactivated like the additional circuit components.

When the aforementioned memory elements or a state machine is used, the ability to control the level converter also assures that optionally no undefined signals are supplied with the signal lines that are connected to the memory elements and lead to temporarily deactivatable circuit components.

In another embodiment of the present invention, it is provided that the first circuit component has a communication interface, which can be connected via a terminal to an external component.

The integrated circuit can be signaled via this communication interface, for instance, that a rest state is to be assumed, in which, for instance, the second circuit component or its voltage regulator and optionally also the level converter are to be deactivated. Likewise, an activation of the second circuit component or its voltage regulator can be initiated by an appropriate data transmission to the integrated circuit via the communication interface.

In another embodiment of the integrated circuit of the invention, it is provided that the integrated circuit has at least one circuit component for realizing a radio transceiver. For instance, this type of radio transceiver can be compatible with the IEEE 802.15.4/ZigBee standard or the like. The integration of a radio transceiver into the integrated circuit of the invention is especially expedient owing to the ability to control the level converter of the invention and the attendant increased flexibility and reliability of the integrated circuit, particularly also during a temporary deactivation of the second or additional circuit components. Because of the increased reliability and the possibility of reducing the power consumption of circuit components, for instance, sensor elements or other assemblies with a radio interface, which also have a relatively high operating time of, for instance, more than 2 years, also during exclusive battery operation, can be realized with the integrated circuit of the invention.

The high operating time is particularly expedient when large sensor networks are to be constructed, which have, for instance, several hundred sensor elements, of which each sensor element contains an integrated circuit of the invention and optionally additional components such as, e.g., sensors and the like. The high reliability and operating time of the integrated circuit of the invention makes it possible to lengthen the maintenance intervals for the respective sensor elements or makes maintenance completely superfluous. In this way, in particular the maintenance costs in conventional systems, e.g., for changing the battery, etc., can be reduced, as a result of which the use of large sensor networks becomes economical.

Apart from a radio transceiver, it is also possible to integrate additional circuit components into the integrated circuit of the invention, which, e.g., can be temporarily deactivated during a rest state and in which an at least partial storage of their operating information within the first circuit component is expedient.

A method is also provided to further achieve the object of the present invention, wherein the level converter of the first circuit component is optionally activated or deactivated, in order to enable or prevent a data exchange between the first circuit component and the second circuit component.

A voltage regulator for supplying the second circuit component and/or additional circuit components can be deactivated by the first circuit component in order to reduce the power consumption of the integrated circuit.

Another embodiment of the method of the invention provides that the voltage regulator for supplying the second circuit component and/or additional circuit components is activated by the first circuit component.

It is also advantageous when the level converter is activated after the voltage regulator, for example, after the elapse of a predefined waiting time since the activation of the voltage regulator. This assures that a data exchange through the level converter can occur only when the circuit component supplied by the voltage regulator is properly supplied with its operating voltage and accordingly transmits valid signals through the level converter to the first circuit component. In this method variant, the waiting time is to be selected depending on the start-up or operating behavior of the voltage regulator to be activated or the circuit component supplied by it.

Another embodiment provides that the level converter is activated only when the voltage regulator has signaled the achieving of its normal operation, in which the voltage regulator delivers its nominal output voltage. The signaling can occur, for example, by a control line provided for this, which connects the voltage regulator to a control logic provided in the first circuit component.

In general, a control of the level converter and/or of voltage regulators can occur by a control logic which is provided in the first circuit component and which can also be realized, for example, in the form of a state machine.

Another embodiment provides that the level converter is deactivated before the voltage regulator, so that a data exchange through the level converter is effectively prevented also during the deactivation of the voltage regulator.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1a shows a schematic block diagram of an integrated circuit according to an embodiment of the present invention;

FIG. 1b illustrates another embodiment of the integrated circuit;

FIG. 2 illustrates a sensor network realized with the use of the integrated circuit of the invention;

FIG. 3a is a flowchart of a first embodiment of the method of the invention; and

FIG. 3b is a flowchart of another embodiment of the method of the invention.

### DETAILED DESCRIPTION

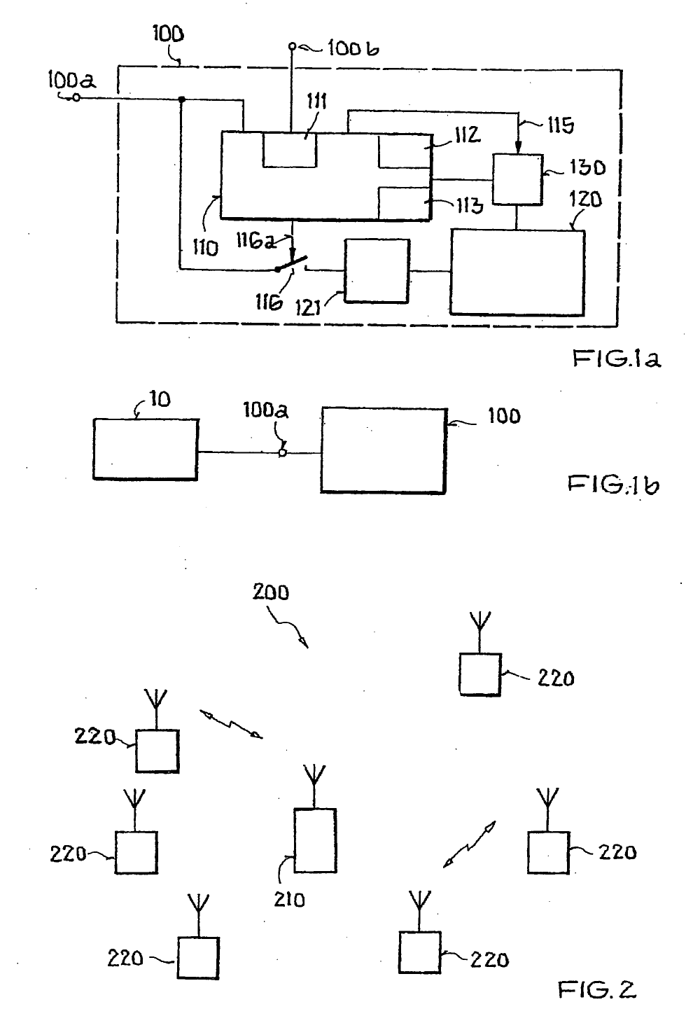

FIG. 1a shows schematically a block diagram of an integrated circuit 100 of the invention. Integrated circuit 100 has a first circuit component 110, which is connected via a level converter 130 to a second circuit component 120. The connection has one or more data or control lines, which are not described in greater detail, by which signals are transmitted between the first and the second circuit component.

First circuit component 110 is realized using a CMOS semiconductor technology with feature sizes of about 0.36 μm and therefore has an operating voltage range of about 1.8 V to about 3.75 V. A voltage supply of first circuit component 110 of integrated circuit 100 can therefore occur via an external voltage source (not shown in FIG. 1a) directly connected to terminal 100a.

Second circuit component 120 is realized using a CMOS semiconductor technology with feature sizes of about 0.18 μm and therefore has an operating voltage range of about (1.8±10%) V. Accordingly, provided in the integrated circuit 100 of the invention is a voltage regulator 121, which can be connected on the input side also to terminal 100a or to the external voltage source, and which supplies on the output side second circuit component 120 with its operating voltage of about 1.8 V.

According to the different operating voltage ranges of first or second circuit component 110, 120, level converter 130 performs a conversion of the specific voltage level of the signals exchanged between circuit components 110, 120 in a manner known per se.

According to the invention, level converter 130 can be controlled by first circuit component 110, which is symbolized in FIG. 1a by arrow 115 coming from first circuit component 110. In particular, level converter 130 can be selectively activated or deactivated by first circuit component 110 in order to allow or prevent a data exchange between circuit components 110, 120.

It is possible to prevent that undefined signal states, which, e.g., can come temporarily from second circuit component 120, are passed on to first circuit component 110, as a result of which the reliability of integrated circuit 100 is increased. Such undefined signal states can occur, for instance, when second circuit component 120 is deactivated, particularly in order to shift to a rest state or the like. It is also conceivable to deactivate level converter 130 when it is suspected that second circuit component 120 has a disruption of operation or another defect.

An activation of level converter 130, for instance, can occur when a data exchange between first circuit component 110 and second circuit component 120 is to occur, or if it is established that no undefined signal states come from second circuit component 120.

The activation or deactivation of level converter 130 in an embodiment of the present invention can occur with the use of a relatively simple logic circuit, which provides a blocking of one or more signals passed through level converter 130, for example, by one or more AND gates. This logic circuit can be integrated, also at least partially, into level converter 130.

In addition to the blocking of the signals passed through it, level converter 130 in another embodiment of the present invention can also be separated, moreover, from a supply voltage assigned to it (not shown), which is particularly expedient in configurations in which level converter 130 has a non negligible quiescent current uptake. In this case, the blocking of the signals can be carried out by a logic circuit, which is assigned to level converter 130 and, for instance, is disposed between first circuit component 110 and level converter 130. As a result, the occurrence of irregular or undefined signal states at the respective signal inputs of first circuit component 110 is also advantageously avoided, which otherwise could occur due to the separation of level converter 130 itself from its supply voltage.

Voltage regulator 121 of integrated circuit 100 can be controlled by first circuit component 110 according to the invention, which is symbolized in FIG. 1a by switch 116 and arrow 116a coming from first circuit component 110. In other words, voltage regulator 121, like level converter 130, can be optionally activated or deactivated by first circuit component 110. Switch 116 in another embodiment of the invention can also be directly integrated into voltage regulator 121, whereby voltage regulator 121 has a corresponding control line 116a to drive integrated switch 116.

The entire second circuit component 120 as well is simultaneously deactivated by a deactivation of voltage regulator 121, so that as a result particularly also the leakage currents arising during operation of second circuit component 120 do not appear, as a result of which the power consumption of integrated circuit 100 is reduced overall.

Especially advantageously, simultaneously with the deactivation of voltage regulator 121, the data exchange between second circuit component 120 and first circuit component 110 through level converter 130 is also prevented by appropriate deactivation of level converter 130.

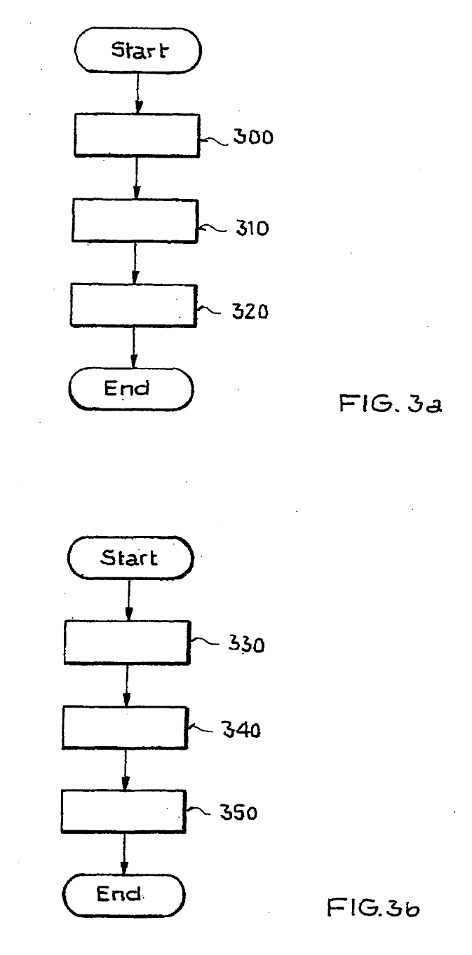

The control of first circuit component 110 occurs according to the invention by a state machine 113, which, for instance, is realized with the use of a plurality of individual memory elements within first circuit component 110. State machine 113 also controls the method sequences of the invention which will be described in greater detail with use of FIGS. 3a and 3b.

In general, state machine 113 can also be used to control additional components of the integrated circuit 100 of the invention. For instance, state machine 113 can also control the second and optionally additional circuit components or store their operating information. A data exchange necessary for this occurs via the connection realized through level converter 130.

The arrangement of state machine 113, according to the invention, in first circuit component 110 is especially advantageous, because first circuit component 110 can be connected via terminal 100a directly to an external voltage source 10, as is shown by way of example in FIG. 1b, and is permanently operable. In particular, the supply to first circuit component 110 is also retained when additional circuit components 120 are temporarily deactivated to reduce the power consumption of integrated circuit 100. In other words, information stored in state machine 113, particularly also operating information of the temporarily deactivated circuit component 120, is retained beyond their deactivation and is available without a delay when the appropriate circuit component 120 is activated again.

In contrast to conventional integrated circuits, a reliable operation of integrated circuit 100 of the invention and its circuit components 110, 120 and retention of stored data are thereby possible, whereas the power consumption is reduced simultaneously by deactivation of selected circuit components 120.

Because of the design of first circuit component 110 using a CMOS semiconductor technology with feature sizes of about 0.36 μm and an appropriately large operating voltage range, for instance, a conventional battery can be used as external voltage source 10.

Alternatively to state machine 113 or in addition hereto, additional memory elements 112 such as, for instance, flip-flops, which store configuration information of circuit components 110, 120 or other operating information to be retained, can also be disposed in first circuit component 110.

In another embodiment of the present invention, it is provided that first circuit component 110 has a communication interface 111 (FIG. 1a), which can be connected via terminal 100b to an external component (not shown in FIG. 1a), such as, for example, another integrated circuit or the like.

Integrated circuit 100 can be signaled via communication interface 111, for example, that a rest state is to be assumed, in which second circuit component 120 or its voltage regulator 121 and optionally also level converter 130 are to be deactivated. Similarly, activation of second circuit component 120 or of voltage regulator 121 can be initiated by an appropriate data transmission via communication interface 111 to integrated circuit 100. Communication interface 111 can be, for instance, an SPI (Serial Peripheral Interface) interface or also an individual control line.

A similar control, particularly activation and deactivation of level converter 130 and of voltage regulator 121, can also be carried out by state machine 113 or another control logic provided in integrated circuit 100.

In another embodiment, it is provided that integrated circuit 100 has at least one circuit component for realizing a radio transceiver. For instance, the radio transceiver can be a transceiver compatible with the IEEE 802.15.4/ZigBee standard.

The integration of a radio transceiver into integrated circuit 100 of the invention is especially expedient owing to the ability to control level converter 130 according to the invention and the attendant increased flexibility and reliability of integrated circuit 100, particularly also during a temporary deactivation of the circuit components, because an especially reliable circuit with an especially low power consumption results with this combination.

For instance, sensor elements or other assemblies with a radio interface, which also have a relatively high operating time of, for instance, more than 2 years, also during exclusive battery operation, can be realized with integrated circuit 100 of the invention. FIG. 2 shows by way of example a sensor network 200, which has a plurality of sensor elements 220, of which each has integrated circuit 100 of the invention (FIG. 1a) and optionally additional components such as, e.g., sensors and the like. The power supply of individual sensor elements 220 occurs in each case by means of a battery integrated into sensor element 220, cf. FIG. 1b.

As already described, the high reliability and operating time of integrated circuit 100 of the invention makes it possible to lengthen the maintenance intervals of the respective sensor elements 220 or makes maintenance completely superfluous. As a result, in particular the maintenance costs in conventional systems, e.g., for changing the battery, etc., can be reduced.

Sensor network 200 of FIG. 2, for instance, uses ZigBee-compatible radio transceivers, which are integrated into integrated circuit 100 of the invention of each sensor element 220 in each case in the form of an appropriate circuit component 120 (FIG. 1a). As indicated in FIG. 2 by double arrows, integration of the ZigBee-compatible radio transceivers enables a wireless data exchange both between different sensor elements 220, as well as between a sensor element 220 and a mobile reading device 210, which can be used, for instance, by an operator, to retrieve in a simple manner sensor data from one or more sensor elements 220.

FIG. 3a shows a first embodiment of the method of the invention, in which integrated circuit 100 (FIG. 1a) is signaled, e.g., via communication interface 111 in step 300 (FIG. 3a) that a rest state is to be assumed, in order to reduce the power consumption of integrated circuit 100. Accordingly, first circuit component 110 in step 310 first deactivates level converter 130, and then first circuit component 110 in step 320 deactivates voltage regulator 121. By deactivating level converter 130 in step 310, it is assured first that the following deactivation of voltage regulator 121 and possibly associated invalid signal states, coming from second circuit component 120, which could occur during deactivation of voltage regulator 121 supplying it, do not lead to invalid signal states at the signal inputs, connected to level converter 130, of first circuit component 110. After the data exchange through level converter 130 has thereby been blocked, in step 320 second circuit component 120 can be shut down as described.

As a result, on the one hand, the power consumption of voltage regulator 121 is minimized and, on the other, no further electrical losses due to leakage currents occur in second circuit component 120 in this state, so that there is an especially effective reduction of the power consumption. As a result of the direct connection of first circuit component 110 to external voltage supply 10, operating information stored in state machine 113 and in memory elements 112 is also reliably retained during the rest state. In this way, second circuit component 120 after a future reactivation can resume its operation at a point defined by the stored operating information.

The flowchart in FIG. 3b shows by way of example the process steps necessary for exiting the rest state assumed according to FIG. 3a. First, it is determined in step 330 that the rest state has been exited. This can also occur by appropriate signaling via communication interface 111 through an external component. It is also possible that a timer unit (not shown), integrated into integrated circuit 100, periodically initiates the exiting of the rest state, etc.

After this, in step 340, first, voltage regulator 121 (FIG. 1a) is activated via switch 116, so that second circuit component 120 is again supplied with its operating voltage of about 1.8 V. Preferably, in step 340, a reset of second circuit component 120 is also carried out to create a defined initial state. Next, in step 350, finally, level converter 130 is activated again, to again allow a data exchange between the now activated second circuit component 120 and first circuit component 110.

To assure that second circuit component 120 is already fully functional during the activation of level converter 130 in step 350 and accordingly emits no undefined signal states, after the activation of voltage regulator 121 in step 340 a predefined waiting time can be maintained before level converter 130 is also activated. Alternatively to this, it is also possible that first circuit component 110 analyzes a response of voltage regulator 121, which indicates the achievement of its normal operating state and thereby the proper supplying of the operating voltage of about 1.8 V to second circuit component 120.

As another alternative hereto, the response of voltage regulator 121 could also act directly on level converter 130, to be able to activate said converter directly, as soon as voltage regulator 121 upon activation by first circuit component 110 has assumed its normal operating state. As a result, the evaluation of the response by first circuit components 110 is advantageously eliminated. In this case, the control or activation of level converter 130 occurs indirectly by means of first circuit component 110. In this variant of the invention, a deactivation, e.g., can be signaled directly by first circuit component 110 only to voltage regulator 121, which passes on the deactivation in turn also to level converter 130. In other words, the control line indicated by arrow 115 in FIG. 1a can be omitted, provided that an appropriate control line is provided between voltage regulator 121 and level converter 130.

In general, apart from the first and second circuit components, additional circuit components can also be integrated into integrated circuit 100 of the invention. In an especially advantageous way, these additional circuit components are also connected via a controllable level converter 130 of the invention to first circuit component 110 and preferably can also be temporarily deactivated by its assigned controllable voltage regulator.

In other words, according to the invention a plurality of controllable level converters can also be provided in integrated circuit 100. Apart from level converters, which convert voltage levels or current levels into one another, electro-optic or electro-mechanical level converters may also be used, whereby the second or additional circuit components, inter alia, connected via such level converters, can also be designed as photonic or mechanical, particularly micromechanical, circuit components or as hybrid circuit components. A piezoelectric element can be used, for instance, to realize an electromechanical level converter.

The first, permanently operating circuit component 110 is realized very expediently using a CMOS semiconductor technology with relatively large feature sizes, so that it has low leakage currents. Furthermore, it is expedient to integrate the components that in fact must operate constantly into the first, permanently operating circuit component 110. All other components, which can be deactivated temporarily, are advantageously disposed in the additional circuit components 120. These additional circuit components 120 can be realized advantageously also using one or more different CMOS semiconductor technologies with relatively small feature sizes, so that overall a higher integration density can be achieved in integrated circuit 100 of the invention. The leakage currents, increasing with declining feature sizes, and the corresponding increase in the power consumption of the relevant circuit components can be at least compensated by temporary deactivation.

The quiescent current uptake of integrated circuit 100, in comparison with conventional integrated circuits, can be reduced by at least an order of magnitude by means of the combination of controllable level converter 130 of the invention with the temporary deactivation of some circuit components.

The principle of the controllable level converter 130, according to the invention, can also be used in integrated circuits in general, which are based on semiconductor technologies different from the CMOS semiconductor technology. The provision of a plurality of controllable level converters, which provide for conversion of signals between several different operating voltage ranges, is also conceivable.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An integrated circuit comprising:
at least one first circuit component;
a level converter; and
at. least one second circuit component, the first circuit component being connectable via the level converter to the second circuit component,
wherein the level converter is selectively activated or deactivated by the first circuit component in order to enable or prevent a data exchange between the first circuit component and the second circuit component.

2. The integrated circuit according to claim 1, wherein the level converter is configured so that in its deactivated state, the level converter emits a predefined signal to the first circuit component and/or to the second circuit component.

3. The integrated circuit according to claim 1, wherein the first circuit component has a first operating voltage range, and wherein the second circuit component has a second operating voltage range, which is different from the first operating voltage range.

4. The integrated circuit according to claim 1, wherein the first circuit component has a greater operating voltage range than the second circuit component.

5. The integrated circuit according to claim 1, further comprising a terminal for connecting the integrated circuit to an external voltage source, the terminal being connected directly to the first circuit component.

6. The integrated circuit according to claim 1, further comprising at least one voltage regulator, which is activated or deactivated by the first circuit component, for supplying power to the second circuit component and/or additional circuit components.

7. The integrated circuit according to claim 1, further comprising at least one memory element or a flip-flop that is provided in the first circuit component and/or further comprising a state machine that is provided in the first circuit component.

8. The integrated circuit according to claim 1, wherein the first circuit component has a communication interface that is connected via a terminal to an external component.

9. The integrated circuit according to claim 1, wherein the integrated circuit further comprises at least one additional circuit component for realizing a radio transceiver.

10. A method for operating an integrated circuit having at least one first circuit component and at least one second circuit component, the method comprising:
providing a level converter for connecting the first circuit component to the second circuit component; and
selectively activating or deactivating the level converter by the first circuit component in order to enable or prevent a data exchange between the first circuit component and the second circuit component.

11. The method according to claim 10, wherein a voltage regulator for supplying the second circuit component and/or additional circuit components is deactivated by the first circuit component in order to reduce the power consumption of the integrated circuit.

12. The method according to claim 11, wherein the voltage regulator is activated by the first circuit component.

13. The method according to claim 11, wherein the level converter is activated after the voltage regulator or after an elapse of a predefined waiting time since the activation of the voltage regulator.

14. The method according to claim 13, wherein the level converter is activated only when the voltage regulator has signaled the achieving of its normal operation, in which the voltage regulator delivers its nominal output voltage.

15. The method according to claim 11, wherein the level converter is deactivated before the voltage regulator.
